(19) United States
(12) Patent Application Publication
(10) Pub. No.: US 2012/0206284 A1
(43) Pub. Date: Aug. 16, 2012

(54) INTERPOLATING DIGITAL-TO-ANALOG CONVERTER WITH SEPARATE BIAS CURRENT SOURCE FOR EACH DIFFERENTIAL INPUT TRANSISTOR PAIR

(75) Inventor: Iulian Constantin Gradinariu, Colorado Springs, CO (US)

(73) Assignee: LINEAR TECHNOLOGY CORPORATION, Milpitas, CA (US)

(21) Appl. No.: 13/025,045

(22) Filed: Feb. 10, 2011

(51) Int. Cl. H03M 1/66

(52) U.S. Cl. 341/144

(57) ABSTRACT

The most significant portion of a digital word may be converted into a high and a low analog voltage representative, respectively, of the highest and lowest possible values which a digital word could have with the most significant portion. An analog output may be produced by interpolating between the high and the low analog voltage in accordance with the value of the least significant portion of the digital word. A differential transconductance input stage may have pairs of differential input transistors. For each differential input transistor pair, a separate bias current circuit may provide a bias current to the differential input transistor pair, separate from the bias current provided to the other differential input transistor pairs. All bias current circuits may be identical in a linear interpolator. The transconductance input stage may have a gain of at least 20 dB and may result in an integral non-linearity in the analog output of no more than 0.08 times the weight of the least significant bit of the digital word.

### BACKGROUND

1. Technical Field

This disclosure relates to digital-to-analog converters, including digital-to-analog converters which interpolate between a high and low analog voltage.

2. Description of Related Art

A digital-to-analog converter converts a digital word into an analog output which is representative of the value of the digital word.

Some digital-to-analog converters include an interpolation section which interpolates between a high and low analog voltage. The most significant portion of the digital word may be converted into a (a) high analog voltage which is representative of the highest possible value which the digital word may have in view of the most significant portion and (b) a low analog voltage which is representative of the lowest possible value which the digital word may have with the most significant portion. An interpolation circuit may be used to interpolate between the high and the low analog voltage based on the value of the least significant portion of the digital word.

The output voltage of such a circuit may vary from its ideal value due to nonlinearities in the circuitry. The largest deviation from the ideal value may be referred to as the integral nonlinearity of the circuit. This integral nonlinearity can be greater than is needed for certain applications.

Efforts to reduce the integral nonlinearity of an interpolating digital-to-analog converter have included the use of source degeneration to linearize devices in the circuit. However, source degeneration can significantly reduce the gain of the interpolation circuitry and increase the layout area of the circuit. Both consequences may be undesirable in certain applications.

### SUMMARY

A digital-to-analog converter may convert a digital word having a most and a least significant portion into an analog output which is representative of the value of the digital word. A most significant sub-word digital-to-analog converter may convert the most significant portion of the digital word into a (a) high analog voltage representative of the highest possible value which a digital word could have with the most significant portion and (b) a low analog voltage representative of the lowest possible value which a digital word could have with the most significant portion. A least significant sub-word digital-to-analog converter may produce the analog output by interpolating between the high and the low analog voltage in accordance with the value of the least significant portion of the digital word. The least significant sub-word digital-to-analog converter may include a differential transconductance input stage having pairs of differential input transistors. For each differential input transistor pair, a separate bias current circuit may provide a bias current to the differential input transistor pair separate from the bias current provided to the other differential input transistor pairs. A switch network may provide signals to the differential transconductance input stage which are representative of the least significant portion of the digital word.

The sub-word digital-to-analog converters may be configured such that the integral non-linearity in the analog output is no more than 0.08 or 0.04 times the weight of the least significant bit in the digital word and/or no more than 0.2 mV.

The transconductance input stage may provide a gain of at least 10 or 20 dB.

Each of the bias current sources may cause the differential input transistor pair which it biases to both operate in the strong overdrive or in the sub-threshold region.

The differential input transistors and the bias current sources may provide linear or binary weighted interpolation.

The differential transconductance input stage may not linearize the differential input transistors with source degeneration.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 illustrates an example of a prior art interpolating digital-to-analog converter which may have an integral nonlinearity which is too high for certain applications.

FIG. 2 illustrates an example of a prior art interpolating digital-to-analog converter which uses source degeneration to reduce its integral nonlinearity, but which may have a gain which is too low and which may require a layout area which is too great for certain applications.

FIG. 3 illustrates an example of an interpolating digital-to-analog converter which uses separate bias current sources to reduce its integral nonlinearity, without significantly reducing the gain or requiring a significantly larger layout area.

FIG. 4 is an example of a graph comparing the nonlinearity of the interpolating digital-to-analog converters illustrated in FIG. 1 and FIG. 3.

FIG. 5 is an example of a graph comparing the nonlinearity of a HSPICE simulation of the interpolating digital-to-analog converters illustrated in FIG. 1 and FIG. 3.

FIG. 6 illustrates an alternate configuration for the interpolating digital-to-analog converter illustrated in FIG. 3 which uses the interpolator in a comparator rather than an amplifier.

### DETAILED DESCRIPTION OF ILLUSTRATIVE EMBODIMENTS

Illustrative embodiments are now described. Other embodiments may be used in addition or instead. Details which may be apparent or unnecessary may be omitted to save space or for a more effective presentation. Some embodiments may be practiced with additional components or steps and/or without all of the components or steps which are described.

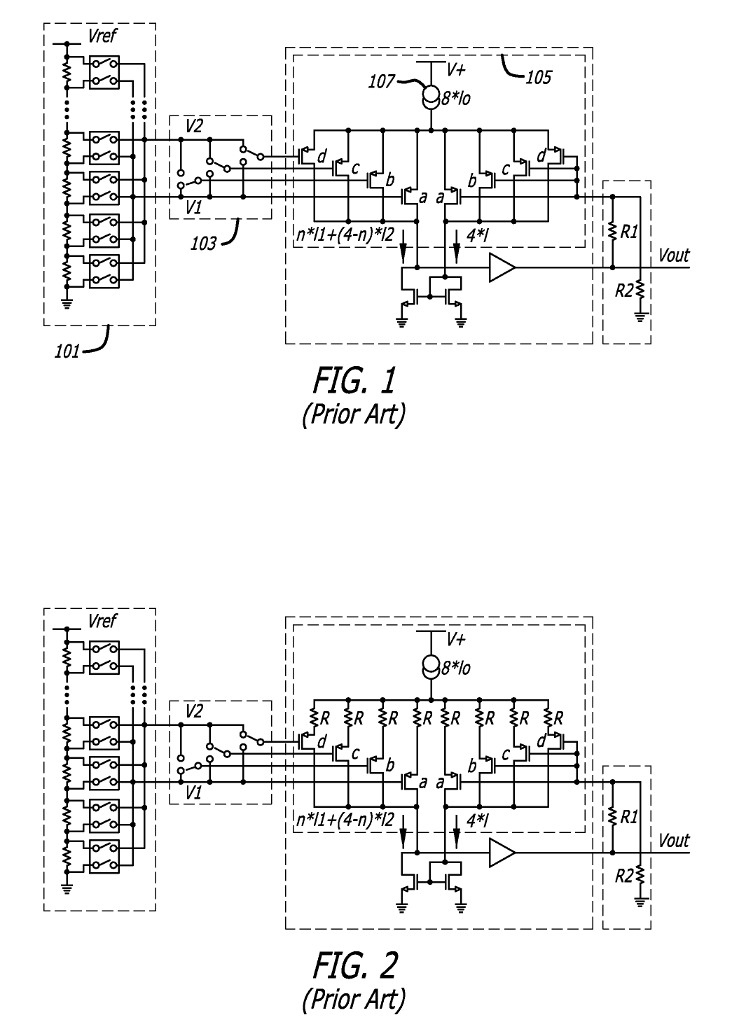

FIG. 1 illustrates an example of a prior art interpolating digital-to-analog converter which may have an integral nonlinearity which is too high for certain applications.

This interpolating digital-to-analog converter is configured to convert a digital word having a most and a least significant portion into an analog output which is representative of the value of the digital word. It includes a most significant sub-word digital-to-analog converter 101 which is configured to convert the most significant portion of the digital word into both a high and a low analog voltage. The high analog voltage is representative of the value of a digital word having the most significant portion of the digital word and a least significant portion with the greatest possible value. The low analog voltage is representative of the value of a digital word, again having the most significant portion of the digital word, but with a least significant portion with the lowest possible value.

As illustrated in FIG. 1, one approach for implementing the most significant sub-word digital-to-analog converter is by using a network of switches to deliver an output which is representative of the voltage across a selected one of a ladder of resistors. The particular resistor which is selected may be based on the value of the most significant portion of the digital word.

The circuit also includes a least significant sub-word digital-to-analog converter which is configured to produce the analog output by interpolating between the high and the low analog voltage from the most significant sub-word digital-to-analog converter 101 in accordance with the value of the least significant portion of the digital word. The least significant sub-word digital-to-analog converter includes a differential transconductance input stage 105 which has pairs of differential input transistors a, b, c, and d, and a current source 107. A switch network 103 is configured to provide signals to the differential transconductance input stage 105 which are representative of the least significant portion of the digital word.

This voltage interpolator in this circuit is a two-bit voltage interpolator. A comparable circuit may be used for any different number of bits.

The interpolated voltage V may be defined by the following equation:

V=Vout*R2/(R1+R2)=n/4*V1+(1−n/4)*V2+e=V′+e (1)

where n is the decimal interpolation code 0≦n≦3 controlling the switches, e is the integral nonlinearity (INL) error, V′ is the ideal interpolated value, and V is the voltage for which the output currents of the interpolator are equal. In this case:

4*I=n*I1+(4−n)*I2 (2)

Assuming the MOS devices work in strong inversion and are identical, equation (2) above becomes:

4*(V−Vt)̂2=n*(V1−Vt)̂2+(4−n)*(V2−Vt)̂2 (3)

By replacing equation (1) in equation (3), and neglecting ê2, the following error term is obtained:

e=−n/8*(1−n/4)*(V1−V2)̂2/(V−Vt)=−2*n*(4−n)*(LSB)̂2/Vod (4)

where LSB=(V1−V2)/4 is the LSB of the interpolator and Vod is the MOS voltage overdrive. In this case, a parabolic-shaped error function is obtained with end-of scale zeroes and mid-scale absolute maximum:

emax=−2*(LSB)̂2/Vod (5)

For example, assuming LSB=8 mV and Vod=64 mV, emax=−2 mV=−LSB/4.

More details about these as well as other components in the circuit are set forth in U.S. Pat. No. 5,859,606 (issued Jan. 12, 1999), the contents of which are incorporated herein by reference.

FIG. 2 illustrates an example of a prior art interpolating digital-to-analog converter which uses source degeneration to reduce its integral nonlinearity, but which may have a gain which is too low and which may require a layout area which is too great for certain applications.

FIG. 2 uses local negative feedback (source degeneration) in order to linearize the interpolating MOS devices. Replica MOS devices working in the triode region may be used as degeneration resistors R. This technique may be effective in reducing the integral nonlinearity (INL) error. However, it may also reduce the gain of the interpolator by the same amount, according to the following equation:

emax′=−4*(LSB)̂2*/(Vod+R*I)=emax/(1+R*1/Vod) (6)

where R*I is the amount of source degeneration. Thus, for example, a 95% reduction in the integral nonlinearity (INL) error may entail a 26 dB gain loss in the interpolator. Adding source degeneration may also increase the layout area of the circuit.

More details about these as well as other components in the circuit illustrated in FIG. 2 are set forth in U.S. Pat. No. 5,396,245 (issued Mar. 7, 1995), the content of which is incorporated herein by reference.

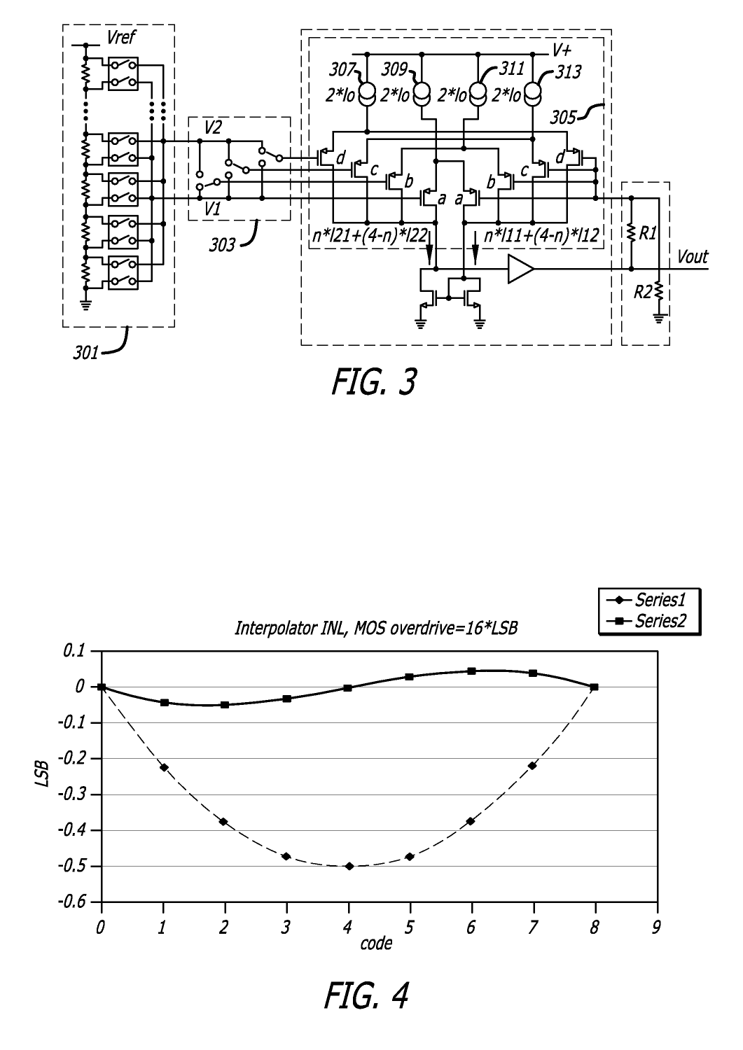

FIG. 3 illustrates an example of an interpolating digital-to-analog converter which uses separate bias current sources to reduce its integral nonlinearity, without significantly reducing the gain or requiring a significantly larger layout area.

The interpolating digital-to-analog converter illustrated in FIG. 3 may include a most significant sub-word digital-to-analog converter 301 and a least significant sub-word digital-to-analog converter which may include a switch network 303 and a differential transconductance input stage 305. Each of these components may be the same as or comparable to their corresponding component in FIG. 1 as described in more detail above and in U.S. Pat. No. 5,859,606 (issued Jan. 12, 1991).

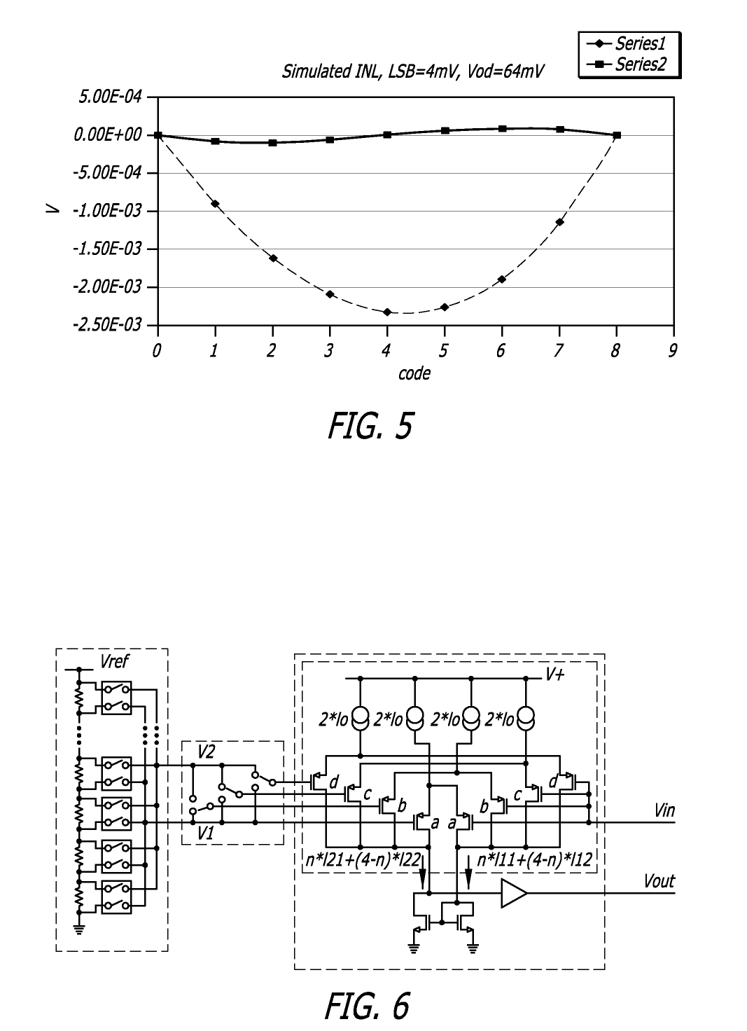

One significant difference, however, may be that the differential transconductance input stage 305 may include a separate bias current circuit for each differential input transistor pair a, b, c, and d, such as separate bias current circuits 307, 309, 311, and 313. Each separate bias current circuit may be configured to provide a bias current to the differential input transistor pair with which it is associated, separate from the bias current provided to the other differential input transistor pairs. All of the bias current circuits may be identical in a linear interpolator. Unlike the circuit illustrated in FIG. 2, moreover, the circuit illustrated in FIG. 5 may not linearize the differential input transistors by providing source degeneration. As a consequence, the transconductance input stage 305 may provide gains of at least 10 or even 20 dB.

Each of the bias current sources 307, 309, 311, and 313 may be configured to cause the differential input transistor pair which it biases to both operate in either the strong inversion region or the sub-threshold region.

By providing a separate current source for each differential input transistor pair, the closed-loop equilibrium current equation may be:

n*I11+(4−n)*I12=n*I21+(4−n)*I22 (7)

where I11, I21, I12, and I22 are the output currents of the individual differential pairs connected to V, V1 and V, V2 gate voltages, respectively. Thus:

I11+I21=I12+I22=2*I0 (8)

Assuming that input MOS devices are identical and operate in the strong inversion region, this may result in:

I11/β=Vod11̂2=(V−Vs1−Vt)̂2 and I21/β=Vod21̂2=(V1−Vs1−Vt)̂2 (9)

I12/β=Vod12̂2=(V−Vs2−Vt)̂2 and I22/β=Vod22̂2=(V2−Vs2−Vt)̂2 (10)

where β=μ*Cox*W/L is the gain of the MOS device and Vs1, Vs2 are the source voltages of individual differential pairs connected to gate voltages V, V1 and V, V2, respectively. Combining equation (8) with equations (9) and (10) may result in:

I11=I0+2*β*(V−V1)*sqrt[I0/β−(V−V1)̂2/4]

I21=I0−2*β*(V−V1)*sqrt[I0/β−(V−V1)̂2/4] (11)

I12=I0+2*β*(V−V2)*sqrt[I0/β−(V−V2)̂2/4]

I22=I0−2*β*(V−V2)*sqrt[I0/β−(V−V2)̂2/4] (12)

By replacing equations (11) and (12) in equation (7), this may result in:

n̂2*(V−V1)̂2[I0/β−(V−V1)̂2/4]=(4−n)̂2*(V−V2)̂2*[I0/β−(V−V2)̂2/4] (13)

By replacing equation (1) in equation (13), and again neglecting ê2, this may result in an error term of:

e″=−n/16*(1−n/2)*(1−n/4)*(V1−V2)̂3/[2*Vod̂2−n/4*(1−n/4)*(V1−V2)̂2] (14)

In a typical application, considering again that V1−V2=4*LSB=32 mV and Vod=64 mV, n/4*(1−n/4)*(V1−V2)̂2≦1024 mV̂2 versus 2*Vod̂2=8192 mV̂2. can be neglected, equation (14) may simplify to:

e″=−LSB*n/8*(1−n/2)*(1−n/4)*(4*LSB/Vod)̂2 (15)

where LSB=(V1−V2)/4 is the LSB of the interpolator and Vod is the MOS voltage overdrive. This may result in an S-shaped error function with end-of scale and mid-scale zeroes and an absolute maximum:

emax″=−LSB*1/8*(1−1/2)*(1−1/4)*(4*LSB/Vod)̂2=emax*3/8*LSB/Vod (16)

For example, assuming again LSB=8 mV and Vod=64 mV, the circuit illustrated in FIG. 3 may achieve a 95.3% improvement in integral nonlinearity (INL) error versus the circuit illustrated in FIG. 1.

Moreover, since the error in the circuit illustrated in FIG. 3 may be proportional to (LSB/Vod)̂2, while state of the error in the circuit illustrated in FIG. 1 may be proportional to (LSB/Vod), operating the input devices in strong inversion (large Vod) may have increased benefits in the interpolator illustrated in FIG. 3.

In the case of 3 bit interpolators, n=8 and equations (4), (5) (15), and (16) may become:

e=−n/16*(1−n/8)*(V1−V2)̂2/(V−Vt)=−n/2*(8−n)*(LSB)̂2/Vod (17)

emax=−8*(LSB)̂2/Vod (18)

e″=−LSB*n/8*(1−n/4)*(1−n/8)*(8*LSB/Vod)̂2 (19)

emax″=−LSB*2/8*(1−2/4)*(1−2/8)*(8*LSB/Vod)̂2=emax*3/4*LSB/Vod (20)

Assuming again n=8, LSB=4 mV and Vod=64 mV, the circuit illustrated in FIG. 3 may achieve the same 95.3% improvement in INL error versus the circuit illustrated in FIG. 1.

FIG. 4 is an example of a graph comparing the nonlinearity of the interpolating digital-to-analog converters illustrated in FIG. 1 and FIG. 3. This is based on the case of a three bit interpolator (n=8, LSB=4 mV and Vod=64 mV). A different number of bits may be used instead.

FIG. 5 is an example of a graph comparing the nonlinearity of a HSPICE simulation of the interpolating digital-to-analog converters illustrated in FIG. 1 and FIG. 3.

A comparison of equation (6) and (16) shows that comparable integral nonlinearities may be achieved in both circuits, but without a commensurate loss of gain or a significant increase in layout area of the circuit. The circuit illustrated in FIG. 3 may result in an integral nonlinearity in the analog output which is no more than 0.08 or even 0.04 times the weight of the least significant bit in the digital word which is to be converted. In absolute terms, the integral nonlinearity may be no more than 0.2 mV.

FIG. 6 illustrates an alternate configuration for the interpolating digital-to-analog converter illustrated in FIG. 3 which uses the interpolator in a comparator rather than an amplifier.

The components, steps, features, objects, benefits and advantages which have been discussed are merely illustrative. None of them, nor the discussions relating to them, are intended to limit the scope of protection in any way. Numerous other embodiments are also contemplated. These include embodiments which have fewer, additional, and/or different components, steps, features, objects, benefits and advantages. These also include embodiments in which the components and/or steps are arranged and/or ordered differently.

For example, the differential input transistors and the bias current sources which are illustrated in FIG. 3 are configured to provide linear interpolation. They may instead be configured to provide binary-weighted interpolation by using binary weighted width/length devices in the transconductance input stage differential pairs and associated individual bias current sources In this case the bias current sources are not identical any more, bur are matched and binary weighted. Similarly, the least significant sub-word digital-to-analog converter illustrated in FIG. 3 is configured to interpolate based on a least significant portion of a digital word which has two bits. It may instead be configured to interpolate based on a least significant portion which has a different number of bits, such as 1, 3, 4, 5, or any larger number of bits. The number of most significant bits may also be different.

The differential input transistors may be biased in the subthreshold region, rather than in the strong inversion region, which may produce similar results.

Unless otherwise stated, all measurements, values, ratings, positions, magnitudes, sizes, and other specifications which are set forth in this specification, including in the claims which follow, are approximate, not exact. They are intended to have a reasonable range which is consistent with the functions to which they relate and with what is customary in the art to which they pertain.

All articles, patents, patent applications, and other publications which have been cited in this disclosure are incorporated herein by reference.

The phrase “means for” when used in a claim is intended to and should be interpreted to embrace the corresponding structures and materials which have been described and their equivalents. Similarly, the phrase “step for” when used in a claim is intended to and should be interpreted to embrace the corresponding acts which have been described and their equivalents. The absence of these phrases in a claim mean that the claim is not intended to and should not be interpreted to be limited to any of the corresponding structures, materials, or acts or to their equivalents.

The scope of protection is limited solely by the claims which now follow. That scope is intended and should be interpreted to be as broad as is consistent with the ordinary meaning of the language which is used in the claims when interpreted in light of this specification and the prosecution history which follows and to encompass all structural and functional equivalents. Notwithstanding, none of the claims are intended to embrace subject matter which fails to satisfy the requirement of Sections 101, 102, or 103 of the Patent Act, nor should they be interpreted in such a way. Any unintended embracement of such subject matter is hereby disclaimed.

Except as stated immediately above, nothing which has been stated or illustrated is intended or should be interpreted to cause a dedication of any component, step, feature, object, benefit, advantage, or equivalent to the public, regardless of whether it is or is not recited in the claims.

The invention claimed is:

1. A digital-to-analog converter for converting a digital word having a most and a least significant portion into an analog output which is representative of the value of the digital word comprising:
a most significant sub-word digital-to-analog converter configured to convert the most significant portion of the digital word into:
a high analog voltage representative of the highest possible value which a digital word could have with the most significant portion; and
a low analog voltage representative of the lowest possible value which a digital word could have with the most significant portion; and
a least significant sub-word digital-to-analog converter configured to produce the analog output by interpolating between the high and the low analog voltage from the most significant sub-word digital-to-analog converter in accordance with the value of the least significant portion of the digital word, the least significant sub-word digital-to-analog converter including:
a differential transconductance input stage having:
pairs of differential input transistors; and
for each differential input transistor pair, a separate bias current circuit configured to provide a bias current to the differential input transistor pair separate from the bias current provided to the other differential input transistor pairs; and
a switch network configured to provide signals to the differential transconductance input stage which are representative of the least significant portion of the digital word.

2. The digital-to-analog converter of claim 1 wherein
the least significant portion of the digital word has a least significant bit; and
the sub-word digital-to-analog converters are configured such that the integral non-linearity in the analog output is no more than 0.08 times the weight of the least significant bit.

3. The digital-to-analog converter of claim 2 wherein the sub-word digital-to-analog converters are configured such that integral non-linearity in the analog output is no more than 0.04 times the weight of the least significant bit.

4. The digital-to-analog converter of claim 1 wherein the sub-word digital-to-analog converters are configured such that the integral non-linearity in the analog output is no more than 0.2 mV.

5. The digital-to-analog converter of claim 1 wherein the differential transconductance input stage is configured not to linearize the differential input transistors using source degeneration.

6. The digital-to-analog converter of claim 1 wherein the transconductance input stage provides a gain of at least 10 dB.

7. The digital-to-analog converter of claim 6 wherein the transconductance input stage provides a gain of at least than 20 dB.

8. The digital-to-analog converter of claim 2 wherein each of the bias current sources are configured to cause the differential input transistor pair which it biases to both operate in the strong inversion region.

9. The digital-to-analog converter of claim 1 wherein each of the bias current sources are configured to cause the differential input transistor pair which it biases to both operate in the sub-threshold region.

10. The digital-to-analog converter of claim 1 wherein the differential input transistors and the bias current sources are configured to provide linear interpolation.

11. The digital-to-analog converter of claim 1 wherein the differential input transistors and the bias current sources are configured to provide binary weighted interpolation.

12. A digital-to-analog converter for converting a digital word having a most and a least significant portion into an analog output which is representative of the value of the digital word comprising:
a most significant sub-word digital-to-analog converter configured to convert the most significant portion of the digital word into:
a high analog voltage representative of the highest possible value which a digital word could have with the most significant portion; and
a low analog voltage representative of the lowest possible value which a digital word could have with the most significant portion; and
a least significant sub-word digital-to-analog converter configured to produce the analog output by interpolating between the high and the low analog voltage from the most significant sub-word digital-to-analog converter in accordance with the value of the least significant portion of the digital word, the least significant sub-word digital-to-analog converter including:
a differential transconductance input stage having:
pairs of differential input transistors; and
a bias current circuit configured to provide bias current to the differential input transistor pairs; and
a switch network configured to provide signals to the differential transconductance input stage which are representative of the least significant portion of the digital word,
wherein:
the differential transconductance input stage is configured not to linearize the differential input transistors using source degeneration;
the least significant portion of the digital word has a least significant bit; and
the sub-word digital-to-analog converters are configured such that the integral non-linearity in the analog output is no more than 0.08 times the weight of the least significant bit.

13. The digital-to-analog converter of claim 12 wherein the sub-word digital-to-analog converters are configured such that the integral non-linearity in the analog output is no more than 0.04 times the weight of the least significant bit.

14. The digital-to-analog converter of claim 12 wherein the sub-word digital-to-analog converters are configured such that the integral non-linearity in the analog output is no more than 0.2 mV.

15. The digital-to-analog converter of claim 12 wherein the transconductance input stage provides a gain of at least 10 dB.

16. The digital-to-analog converter of claim 15 wherein the transconductance input stage provides a gain of at least 20 dB.

17. A digital-to-analog converter for converting a digital word having a most and a least significant portion into an analog output which is representative of the value of the digital word comprising:
a most significant sub-word digital-to-analog converter configured to convert the most significant portion of the digital word into:
a high analog voltage representative of the highest possible value which a digital word could have with the most significant portion; and
a low analog voltage representative of the lowest possible value which a digital word could have with the most significant portion; and
a least significant sub-word digital-to-analog converter configured to produce the analog output by interpolating between the high and the low analog voltage from the most significant sub-word digital-to-analog converter in accordance with the value of the least significant portion of the digital word, the least significant sub-word digital-to-analog converter including:
a differential transconductance input stage having:
pairs of differential input transistors; and
a bias current circuit configured to provide bias current to the differential input transistor pairs; and
a switch network configured to provide signals to the differential transconductance input stage which are representative of the least significant portion of the digital word,
wherein:
the transconductance input stage provides a gain of at least 10 dB;
the least significant portion of the digital word has a least significant bit; and
the sub-word digital-to-analog converters are configured such that the integral non-linearity in the analog output is no more than 0.08 times the weight of the least significant bit.

18. The digital-to-analog converter of claim 17 wherein the transconductance input stage provides a gain of at least 20 dB.

19. The digital-to-analog converter of claim 18 wherein the sub-word digital-to-analog converters are configured such that the integral non-linearity in the analog output is no more than 0.04 times the weight of the least significant bit.

20. The digital-to-analog converter of claim 18 wherein the sub-word digital-to-analog converters are configured such that the integral non-linearity in the analog output is no more than 0.2 mV.
